(19) United States
(12) Patent Application Publication
(10) Pub. No.: US 2002/0158213 A1
(43) Pub. Date: Oct. 31, 2002

(54) Ion implantation apparatus and insulating bushing therefor

(76) Inventors: Yasuhiko Matsunaga, Narita-shi (JP); Masanori Takahashi, Narita-shi (JP); Ryuichi Miura, Narita-shi (JP)

Correspondence Address: APPLIED MATERIALS, INC., 2881 SCOTT BLVD. M/S 2061, SANTA CLARA, CA, 95050, US

(21) Appl. No.: 10/097,504

(22) Filed: Mar. 13, 2002

(30) Foreign Application Priority Data
Mar. 19, 2001 (JP) P2001-078679

(51) Int. Cl. H01J 37/317

(52) U.S. Cl. 250/492.21

(57) ABSTRACT

An ion beam generation unit 2 of an ion implantation apparatus comprises a source chamber 3, and an ion source 6 and an extraction electrode 8 are disposed inside the source chamber 3. An insulating bushing 9 conducting insulation of a high voltage generated by the ion beam generation unit 2 and constituting a part of the source chamber 3 is attached to a main chamber 4 of source chamber 3. The insulating bushing 9 is composed of a cylindrical bushing body 10 secured with respective bolts to the main chamber 4 and a peripheral edge portion 7a of stand 7 and a cylindrical insulating liner 11 provided on the inner side of the bushing body 10. The material of bushing body 10 is a mixture of lead oxide with an epoxy resin. The material of insulating liner is PTFE or ceramics such as Al₂O₃.

### BACKGROUND OF THE INVENTION

1. Field of the Invention

The present invention relates to an ion implantation apparatus and an insulating bushing provided therein.

2. Description of the Related Art

Ion implantation apparatuses conduct ion implantation by irradiation a wafer (substrate) with an ion beam generated in an ion beam generation unit. The ion beam generation unit comprises a chamber; an ion source and an extraction electrode for pulling out the ions generated in the ion source are disposed inside the chamber. A tubular insulating bushing (insulator) conducting a high-voltage insulation and constituting a portion of the chamber is disposed in some of such ion beam generation units.

### SUMMARY OF THE INVENTION

In the above-described ion implantation apparatuses, not only ions, but also impurities (gas) are emitted from the ion source. If such impurities adhere to the inner wall surface of the insulating bushing and are accumulated thereon, they may cause insulation breakdown. Therefore, it is necessary to replace or clean the insulating bushing periodically. However, since the insulating bushings provided in the ion beam generation units are often rather heavy, the replacement or cleaning operation is troublesome or time-consuming.

It is an object of the present invention to provide an ion implantation apparatus and an insulating bushing therefor, that can facilitate the replacement operation.

Thus, the present invention provides an insulating bushing disposed in an ion implantation apparatus, which comprises a cylindrical bushing body and a protective member provided on the inner side of the bushing body.

By providing a protective member as mentioned in the above, when the insulating bushing is composed as a part of a chamber having an ion source inside thereof, for example, the impurities (gas) emitted from the ion source toward the insulating bushing is caused to adhere to the inner wall surface of the protective member. Therefore, even if the impurities adhere to the insulating bushing and are accumulated thereon, it is not necessary to replace the entire insulating bushing and only the protective member may be periodically replaced or cleaned. As a result, the burden to workers is relieved and the working time can be shortened.

The preferred material for the protective member is polytetrafluoroethylene or ceramics. Since those materials have a high resistance to adhesion of contaminants, the service life of the protective member is extended. Therefore, it is not necessary to replace and clean the protective member frequently, which additionally reduces the load on the operator.

It is also preferred that the material of the bushing body be an epoxy resin mixed with lead oxide. In such a case, when X rays are generated inside the insulating bushing, leakage of the X rays from the insulating bushing can be prevented. Furthermore, the strength of the bushing body can be effectively increased by forming the insulating bushing as a part of the chamber of the ion beam generation unit.

It is also preferred that the protective member have a cylindrical shape. As a result, for example, one protective member will suffice and in such a case the replacement of the protective member can be further facilitated.

It is also preferred that portions extending in a wave-like fashion in the axial direction of the bushing body be formed on the outer wall surface of the bushing body and on the inner wall surface of the protective member. As a result, the electric discharge distance created by the insulating bushing is increased and the endurance of the insulating bushing is improved.

Further, the present invention provides an ion implantation apparatus conducting ion implantation by irradiating a substrate with an ion beam generated in an ion beam generation unit, wherein an insulating bushing constituting a part of the chamber of the ion beam generation unit is provided in the ion beam generation unit, and the insulating bushing comprises a cylindrical bushing body and a protective member disposed on the inner side of the bushing body.

When the aforesaid protective member is thus provided in the insulating bushing, the impurities (gas) emitted from the ion source of the ion beam generation unit toward the insulating bushing adhere to the inner wall surface of the protective member. Therefor, even if the impurities adhere to the insulating bushing and are accumulated thereon, it is not necessary to replace the entire insulating bushing and only the protective member may be periodically replaced or cleaned. As a result, the load on the operator is reduced and the operation time is shortened.

Preferably, the ion beam generation unit comprises an ion source disposed inside the chamber and a protective member supporting the ion source and constituting a part of the chamber, and the insulating bushing is provided between the main chamber portion of the chamber and the protective member. As a result, the insulating bushing can be effectively used as a part of the chamber of the ion beam generation unit.

### BRIEF DESCRIPTION OF THE DRAWINGS

FIG. 1 is a schematic structural diagram illustrating an embodiment of the ion implantation apparatus in accordance with the present invention;

FIG. 2 is an enlarged view of the ion beam generation unit shown in FIG. 1; and

FIG. 3 is a cross-sectional view of the insulating bushing shown in FIG. 2.

### DESCRIPTION OF THE PREFERRED EMBODIMENTS

The preferred embodiment of the ion implantation apparatus in accordance with the present invention and an insulating bushing therefor will be described below with reference to the appended drawings.

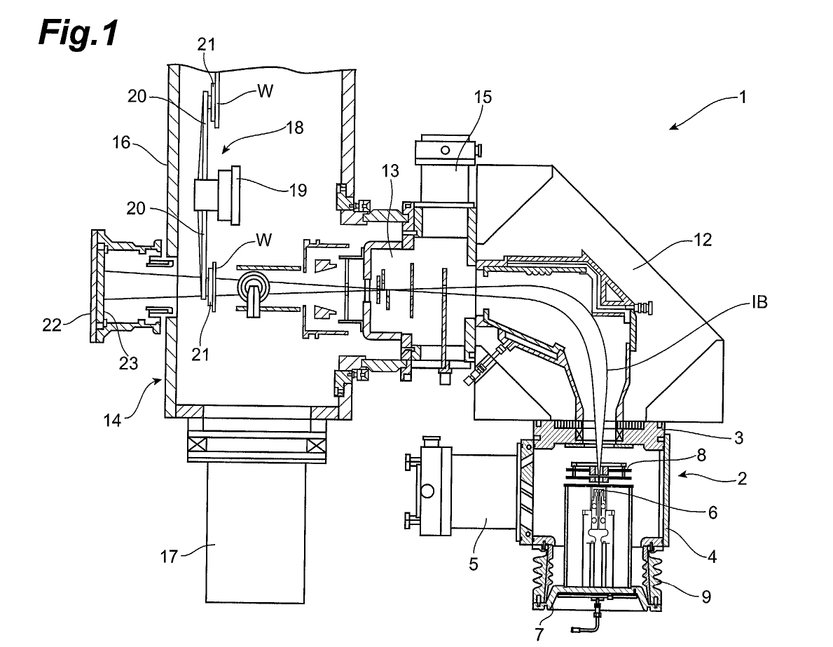

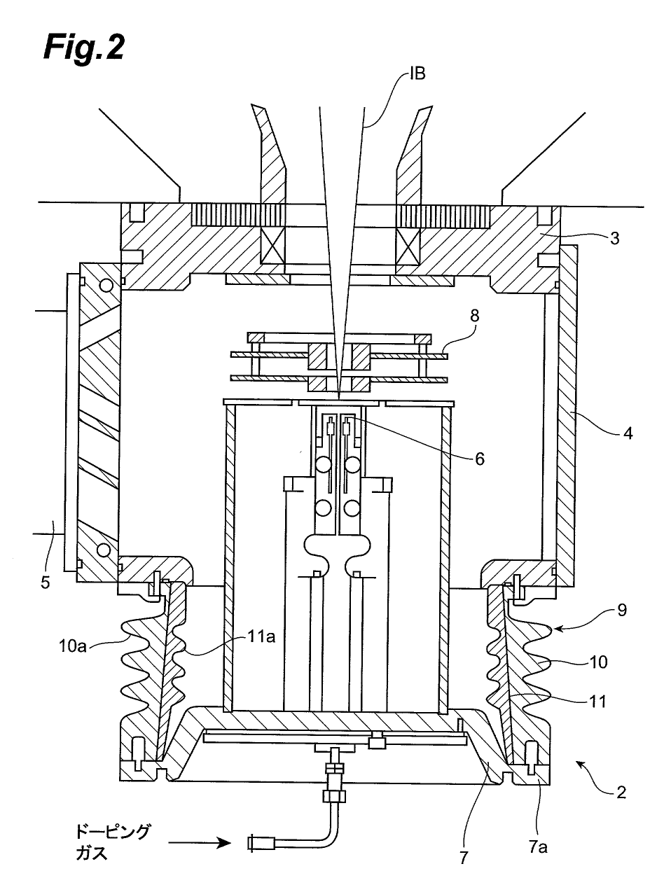

FIG. 1 is a schematic structural diagram illustrating an embodiment of the ion implantation apparatus in accordance with the present invention. In this figure, an ion implantation apparatus 1 comprises an ion beam generation unit 2 for generating an ion beam IB which is to be used for irradiating silicon wafers (substrates) W. The enlarged view of the ion beam generation unit 2 is shown in FIG. 2.

As shown in the figure, the ion beam generation unit 2 comprises a source chamber 3. A turbo pump 5 is connected to a main chamber 4 of the source chamber 3, and the source chamber 3 is evacuated to the prescribed degree of vacuum with the turbo pump 5. An ion source 6 is disposed inside the source chamber 3. The ion source 6 generates an electric discharge in a doping gas introduced by a gas supply source (not shown in the figure), thereby producing a plasma state and ionizing the desired elements (molecules). Furthermore, the ion source 6 is attached to a stand (holding member) 7 forming a part of the source chamber 3. An extraction electrode 8 is disposed on the front surface side of the ion source 6 inside the source chamber 3. The extraction electrode 8 pulls out and accelerates the ions generated by the ion source 6 and generates an ion beam IB.

One end of an insulating bushing 9 constituting a part of the source chamber 3 is attached to the main chamber 4 of source chamber 3. The insulating bushing 9 insulates a high voltage generated in the ion beam generation unit 2. A peripheral edge portion 7a of stand 7 holding the ion source 6 is attached to the outer end of the insulating bushing 9.

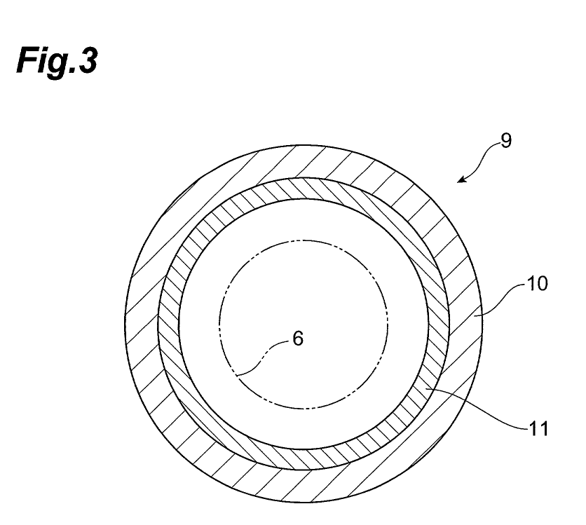

The insulating bushing 9, as shown in FIG. 2 and FIG. 3, is composed of a cylindrical bushing body 10, which is secured with respective bolts to the peripheral edge portion 7a of stand 7 and to the main chamber 4, and a cylindrical insulating liner (protective member) 11 provided on the inner side of the bushing body 10. The outer diameter of the insulating liner 11 is slightly less than the inner diameter of the bushing body 10. As a result, the insulating liner 11 can be easily inserted into the bushing body 10 and pulled out therefrom. Furthermore, when the insulating bushing 9 is assembled as a part of source chamber 3, the insulating liner 11 is sandwiched between the main chamber 4 and the peripheral edge portion 7a of stand 7 and cannot slip out from inside the bushing body 10.

A mixture of lead oxide and an epoxy resin is preferably used as a material of the bushing body 10. In such a case, leakage of X rays to the outside of the source chamber 3 can be prevented when the X rays are generated inside the source chamber 3, for example, by an inverse current of electrons from the pull-out electrode 8. Furthermore, introducing lead oxide guarantees a sufficient strength of the bushing body 10 as a part of source chamber 3.

Further, PTFE (polytetrafluoroethylene) or ceramics such as Al₂O₃ is preferably used as a material of the insulating liner 11. Impurity gas or contaminants emitted from the ion source 6 are present inside the source chamber 3, but employing PTFE or ceramics as a material of insulating liner 11 prevents the adhesion of contamination to the insulating liner 11. As a result, the service life of insulating liner 11 is extended. Other materials with good resistance to adhesion of contamination, for example, epoxy resins with glass coating, may also be used for the insulating liner 11.

A wave-like portion 10a extending in a wave-like fashion in the axial direction of bushing body 10 is formed on the outer edge surface of bushing body 10. Furthermore, a wave-like portion 11a extending in a wave-like fashion in the axial direction of insulating liner 11 is formed on the inner surface of insulating liner 11. When ions are generated from the ion source 6, a high voltage (for example, 80-90 kV) is applied between the main chamber 4 and stand 7, but providing the above-mentioned wave-like portions 10a, 11a increases the electric discharge distance over the insulating bushing 9. As a result, the endurance of insulating bushing 9 is improved.

As shown in FIG. 1, the ion beam IB generated in the above-described ion beam generation unit 2 is transmitted into the ion implantation unit 14 via a mass analysis unit 12 and a mass decomposition unit 13, and ion implantation into the silicon wafers W is conducted in the ion implantation unit 14.

The mass analysis unit 12 comprises an analytical magnet, and only the desired ion species are picked out from the ion beam IB by adjusting the magnetic field strength. The mass decomposition unit 13 passes only the necessary ion beam IB from the ion beam transmitted from the mass analysis unit 12. The mass analysis unit 12 and mass decomposition unit 13 are enclosed in a housing or tube, and the inside thereof is evacuated to the desired vacuum degree with a turbo pump 15.

The ion implantation unit 14 comprises a target chamber 16, and the inside of the target chamber 16 is evacuated to the desired vacuum degree with a cryopump 17. A wafer support 18 for supporting the wafers W which are to be ion implanted is disposed inside the target chamber 16.

The wafer support 18 has a body 19 which is free to rotate or swing. A plurality of arms 20 are provided radially in the body 19 and wafer holders 21 for holding the wafers W are provided on the front end of each arm 20. A Faraday box 22 is linked to the target chamber 16, and a beam stop 23 for stopping the reception of ion beam IB is disposed inside the Faraday box 22.

In the ion implantation apparatus 1 thus constructed, the ion beam IB is generated by the ion beam generation unit 2. Furthermore, wafers W are mounted by a wafer transportation robot (not shown in the figures) on wafer holders 21 of wafer support 18 and the wafer support 18 is rotated or swung. The wafers W are thus irradiated with the ion beam IB and ion implantation is conducted.

In the above-described embodiment, the insulating bushing 9 is composed of the bushing body 10 and insulating liner 11, and the inner wall surface of bushing body 10 is protected with the insulating liner 11. Therefore, impurities or contaminants present inside the source chamber 3 adhered only to the insulating liner 11 and practically did not adhere to the bushing body 10. As a consequence, it is not necessary to replace or clean the entire insulating bushing 9 to prevent the insulation breakdown of insulating bushing 9, and only the insulating liner 11 may be periodically replaced or cleaned.

In such a case, first, the stand 7 holding the ion source 6 is removed from the bushing body 10 of insulating bushing 9, and the insulating liner 11 is pulled out from inside the bushing body 10. Then, an insulating liner 11 which is a new product is inserted into the bushing body 10, and the stand 7 is secured with bolts or the like to the bushing body 10. The old insulating liner 11 having impurities or the like adhered thereto and contamination thereon can be cleaned, if necessary, and reused.

Thus, only the insulating liner 11 is replaced and the bushing body 10 is not required to be removed. Therefore, the parts can be easily replaced and the load on the operator is reduced. Moreover, the operation time can be shortened. In addition, since a material, such as PTFE or ceramics, which has high resistance to adhesion of impurities is used as the material of insulating liner 11, the service life of insulating liner 11 is extended and, therefore, the insulating liner 11 does not require frequent replacement.

The present invention is not limited to the above-described embodiment. For example, the insulating bushing 9 of the above-described embodiment employed one insulating liner 11 inserted into the bushing body 10. The present invention is, however, not limited to such a configuration, and a plurality of cylindrical insulating liners with a small width may be inserted into the bushing body 10. Furthermore, the shape of the insulating liner is not limited to cylindrical shape, provided that the inner wall surface of bushing body 10 is protected.

What is claimed is:

1. An insulating bushing provided in an ion implantation apparatus, comprising a cylindrical bushing body and a protective member provided on the inner side of said bushing body.

2. The insulating bushing of an ion implantation apparatus, according to claim 1, wherein the material of said protective member is polytetrafluoroethylene or ceramics.

3. The insulating bushing of an ion implantation apparatus, according to claim 1, wherein the material of said bushing body is obtained by mixing lead oxide with an epoxy resin.

4. The insulating bushing of an ion implantation apparatus, according to claim 1, wherein said protective member has a cylindrical shape.

5. The insulating bushing of an ion implantation apparatus, according to claim 1, wherein portions extending in a wave-like fashion in the axial direction of said bushing body are provided on the outer wall surface of said bushing body and on the inner wall surface of said protective member.

6. An ion implantation apparatus in which a substrate is subjected to ion implantation by irradiation with an ion beam generated in an ion beam generation unit,
wherein an insulating bushing constituting a portion of the chamber of said ion beam generation unit is provided in said ion beam generation unit; and
said insulating bushing comprises a cylindrical bushing body and a protective member provided on the inner side of said bushing body.

7. The ion implantation apparatus according to claim 6, wherein said ion beam generation unit comprises an ion source disposed inside said chamber and a holding member holding said ion source and constituting a part of said chamber, and said insulating bushing is provided between the main chamber portion of said chamber and said holding member.
